(19) United States
(12) Patent Application Publication
(10) Pub. No.: US 2009/0072900 A1
(43) Pub. Date: Mar. 19, 2009

(54) APPARATUS AND METHOD FOR COMPENSATING FOR NONLINEARITY IN PORTABLE COMMUNICATION TERMINAL

(75) Inventors: Hyung-Weon PARK, Seoul (KR); Seung-Hwan Kim, Suwon-si (KR); Shin-Ho Kim, Suwon-si (KR)

Correspondence Address: THE FARRELL LAW FIRM, P.C., 333 EARLE OVINGTON BOULEVARD, SUITE 701, UNIONDALE, NY, 11553, US

(73) Assignee: SAMSUNG ELECTRONICS CO., LTD., Suwon-si (KR)

(21) Appl. No.: 12/233,275

(22) Filed: Sep. 18, 2008

(30) Foreign Application Priority Data
Sep. 18, 2007 (KR) 2007-0094514

(51) Int. Cl. H03F 1/32; H04L 5/14

(52) U.S. Cl. 330/149; 370/294

(57) ABSTRACT

An apparatus and method for compensating for nonlinearity of a portable communication terminal are provided. The apparatus includes a modem for modulating Transmission (Tx) data, a Digital Pre-Distortion (DPD) mode controller for obtaining power level information and for determining a power on/off state of a DPD unit by using the obtained information in the Tx mode, and the DPD unit for outputting the modulated data input from the modem without performing a DPD operation when power is off, and for outputting the modulated data input from the modem by performing the DPD operation when power is on.

### PRIORITY

This application claims priority under 35 U.S.C. § 119(a) to a Korean patent application filed in the Korean Intellectual Property Office on Sep. 18, 2007 and assigned Serial No. 2007-94514, the contents of which are incorporated herein by reference.

### BACKGROUND OF THE INVENTION

1. Field of the Invention

The present invention relates generally to a portable communication terminal, and more particularly, to an apparatus and method for compensating for nonlinearity of a transmitting part in a portable communication terminal employing a Time Division Duplex (TDD) scheme.

2. Description of the Related Art

As mobile technology has evolved from the conventional voice communication to data communication, a high data throughput has been required in uplink communication. To handle this requirement, technology has been developed to ensure minimum power consumption in a Mobile Station (MS) equipped with a battery. Since power consumption of the MS is greatest in a high power amplifier, efficiency of the high power amplifier has a significant effect on overall efficiency of the MS. A linear characteristic of the high power amplifier has a trade-off relationship with the efficiency of the high power amplifier.

The efficiency of the high power amplifier widely used in portable communication systems can be maximized when the high power amplifier can operate up to near a compression point of 1 dB (hereinafter P_{1dB}) at which a nonlinear amplification occurs. At near the P_{1dB}, the nonlinear amplification causes signal distortion by adding an inter-modulation component to an output signal. The signal distortion results in deterioration of a Signal to Noise Ratio (SNR) for an in-band signal, and acts as an interference between adjacent channels.

To eliminate such a nonlinear component, many linearization techniques such as a feed-forward amplifier have been considered. The feed-forward amplifier is designed so that two Power Amps (PAs) are connected in series to compensate for nonlinear characteristics of the two PAs. Although an excellent linearization characteristic can be obtained using the feed-forward amplifier, the use of the two PAs is disadvantageous in terms of costs and power efficiency.

Another example of well-known linearization techniques is a predistortion linearization technique, in which a distortion level of an output signal from a nonlinear amplifier is predicted and an input signal is reversely predistorted in order to cancel out the distortion to be generated from the amplifier. Although an analog-type predistortion linearization technique using a nonlinear element (e.g., a diode) was popular in an early stage of the predistortion linearization technique, it has shown a shortcoming in that a linearization throughput is significantly limited.

Recently, with the rapid development of digital technologies, digital units can operate with a much faster speed. Thus, a digital predistortion technique has being rapidly developed as a linearization technique using an interoperation with the digital units.

According to the digital predistortion linearization technique, an output signal from an output node of a PA is extracted through a coupler, the extracted signal is down-converted through a mixer, and the down-converted signal is converted into a digital signal through an Analog-to-Digital Converter (ADC). Thereafter, a distortion level is measured using a difference between a delayed input signal and the output signal from the output node, and a predistortion parameter is extracted and then is stored in a Look-Up-Table (LUT). A required predistortion parameter is read from the LUT according to the input signal and is added to the input signal. Accordingly, distortion to be experienced by the PA is compensated for in advance.

The scope of applications of the conventional predistortion linearization technique has been limited to a PA for a Base Station (BS). The conventional technique has a structure in which an output signal is extracted using a closed loop, and the extracted signal is converted into a baseband signal that is converted into a digital signal. This process also requires such components as a coupler, a mixer and an ADC.

Moreover, there is a problem in that requirements (e.g., a bandwidth) to be satisfied for each component are more stringent than other components used in a receiving part or the like. Due to at least these reasons, the conventional technique cannot be applied to a PA for an MS that requires minimum cost and size. In addition, although an amount of power required by the additional elements is negligible in comparison with an amount of power consumed by the PA for the BS, when it is compared with an amount of power consumed by the PA for the MS, the amount of power required by the additional elements is large enough to result in abrupt deterioration in power efficiency of the PA. Since power efficiency is a primary competitive factor of the MS, the deterioration in power efficiency is an additional reason for which the conventional technique cannot be applied to the PA for the MS.

Due to the various problems described above, the predistortion linearization technique has not been applied to the PA of the MS.

Recently, an Orthogonal Frequency Division Multiplexing (OFDM) technique has been introduced to new standards such as Wimax and Long Term Evolution (LTE). One of features of the OFDM technique is a high Peak-to-Average Power Ratio (PAPR). Importance of introduction of the linearization techniques is being reconsidered with the PAPR. In order for a high PAPR signal to pass a PA without distortion, more back-offs are required starting from the P_{1dB}, which can cause an abrupt deterioration in power efficiency of the PA.

Since a channel bandwidth required by a system is rapidly increasing, an Envelop Eliminated and Restoration (EER) technique or a Delta-Sigma Modulation (DSM) technique are becoming more difficult to be introduced as a technique for improving efficiency of the PA. Further, as the use of frequency is becoming more complex, interference with another system has become a further sensitive issue. Thus, a spectrum mask is more limited, necessitating more stringent requirements for linearization in the MS.

Accordingly, there is a need for a predistortion linearization method suitable for a PA for an MS.

### SUMMARY OF THE INVENTION

An aspect of the present invention is to solve at least the above-mentioned problems and/or disadvantages and to provide at least the advantages described below. Accordingly, an aspect of the present invention is to provide an apparatus and method for compensating for nonlinearity of a portable communication terminal.

An aspect of the present invention is to provide an apparatus and method for compensating for nonlinearity of a transmitting part in an open loop manner in a portable communication terminal employing a TDD scheme.

An aspect of the present invention is to provide an apparatus and method for generating in advance a nonlinearity compensation value for nonlinearity factors depending on such parameters as temperature and frequency, by using a Look-Up-Table (LUT) and, when data is transmitted, for compensating for nonlinearity by using the LUT in a portable communication terminal.

An aspect of the present invention is to provide an apparatus and method for compensating for nonlinearity of a portable communication terminal by controlling a Digital PreDistortion (DPD) unit to operate only at a specific power level (e.g., 20 dBm or above) and by controlling the DPD unit to operate in a specific Transmission (Tx) duration other than a full Tx duration at a power level below the specific power level in order to maximize efficiency of a PA of an MS.

In accordance with the present invention, an apparatus for compensating for nonlinearity in a portable communication terminal includes a modem for modulating Tx data input in a Tx mode so as to output modulated data, a DPD mode controller for obtaining power level information by using control information received from a BS and for determining a power on/off state of a DPD unit by using the obtained information in the Tx mode, and the DPD unit, which is powered on/off under the control of the DPD mode controller, for outputting the modulated data input from the modem without performing a DPD operation when power is off, and for outputting the modulated data input from the modem by performing the DPD operation when power is on.

In accordance with the present invention, a method of compensating for nonlinearity in a portable communication terminal includes obtaining power level information by using control information received from a BS, determining a power on/off state of a DPD unit by using the obtained information in a Tx mode, and when power is off, non-performing a DPD operation on the modulated data input from a modem, and when power is on, performing the DPD operation on the modulated data.

### BRIEF DESCRIPTION OF THE DRAWINGS

The above and other aspects, features and advantages of certain preferred embodiments of the present invention will be more apparent from the following detailed description taken in conjunction with the accompanying drawings, in which:

FIG. 1 illustrates a structure of a portable communication terminal using an open-loop Digital PreDistortion (DPD) scheme according to a preferred embodiment of the present invention;

FIG. 2 illustrates a method of controlling a DPD mode in a portable communication terminal according to a preferred embodiment of the present invention;

FIG. 3 illustrates a DPD method in a portable communication terminal according to a preferred embodiment of the present invention; and

FIG. 4 illustrates a preferred frame structure of a Time Division Duplex (TDD) system.

### DETAILED DESCRIPTION OF THE PREFERRED EMBODIMENTS

Preferred embodiments of the present invention will be described below with reference to the accompanying drawings. In the following description, well-known functions or constructions are not described in detail for the sake of clarity and conciseness.

Hereinafter, an apparatus and method for compensating for nonlinearity of a portable communication terminal will be described.

A close loop for feedback in the conventional technique is open in the present invention. Thus, a coupler, a mixer, and an Analog-to-Digital Converter (ADC) used in a feedback part are not necessary. As a result, cost is negated for those additional components. Further, current used in the mixer and the ADC is no longer applied, causing an increase in power efficiency.

However, the opening of the close loop results in a need for a new method for updating a predistortion parameter based on a temperature change. This can be solved when the predistortion parameter is predetermined and stored in an LUT by considering the temperature change. A PA for an MS has a significantly smaller absolute output power variation than a PA for a BS, and also has a relatively small characteristic change depending on temperature. According to such a characteristic of the PA for the MS, increase in the number of required parameters is minimized, and thus increase in an LUT size is minimized. Therefore, the main aspects of the present invention can be achieved. In addition, cost and an absolute area, which are required to increase the LUT size, are also minimized with the development of memory technologies.

The present invention to be described below discloses a timing control method for a further effective system operation while providing control so that power of a Digital PreDistortion (DPD) unit is on/off according to a magnitude of Tx power in order to maximize efficiency of the PA for the MS. In other words, since the PA for the MS shows nonlinearity at a specific power level (e.g., 20 dBm or above), to minimize power consumption of the MS, the PA is constructed such that the DPD unit operates only at a power level at which the PA shows nonlinearity.

Herein, at a power level below the specific power level, the DPD unit operates only in a specific Tx duration other than a full Tx duration, thereby minimizing the power consumption of the MS. In addition, a nonlinearity compensation value for nonlinearity factors depending on such parameters as temperature and frequency, are generated in advance by using an LUT, and when data is transmitted, nonlinearity is compensated for by using the LUT.

Although a TDD-based portable communication system will be described as an example in the following description, the present invention may also apply to additional types of portable communication systems.

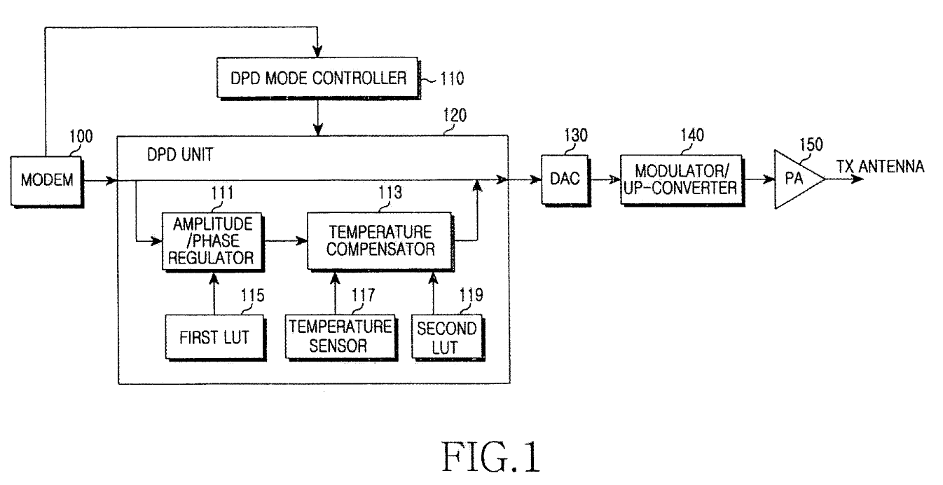

FIG. 1 illustrates a structure of a portable communication terminal using an open-loop DPD scheme according to the present invention.

Referring to FIG. 1, the portable communication terminal includes a Modulator & Demodulator (hereinafter modem) 100, a receiving part (not shown), and a transmitting part. The transmitting part includes a DPD mode controller 110, a DPD unit 120, a Digital-to-Analog Converter (DAC) 130, a modulator/up-converter 140, and a Power Amp (PA) 150. The DPD unit 120 includes an amplitude/phase regulator 111, a temperature compensator 113, a first LUT 115, a temperature sensor 117, and a second LUT 119. Although the DPD mode controller 110 and the modem 100 are separately implemented herein, the function of the DPD mode controller 110 can be included in the modem 100.

The modem 100 demodulates Reception (Rx) data input from the receiving part in an Rx mode and outputs the demodulated data. Further, the modem 100 modulates Tx data input in a Tx mode and outputs the modulated data to the DPD unit 120 of the transmitting part. Furthermore, the modem 100 receives a power level, which is to be output through the PA 150, and location information of an assigned Tx symbol from a MAP information receiver (not shown), and then outputs the received information to the DPD mode controller 110. The MAP information receiver (not shown) receives a MAP from a BS in downlink, obtains the power level to be output through the PA 150 and the location information of the assigned Tx symbol, and thereafter outputs the obtained information to the modem 100.

Upon receiving from the modem 100 the power level to be output through the PA 150 and the location information of the assigned Tx symbol, the DPD mode controller 110 determines whether the power level is less than a specific power level, e.g., 20 dBm. If the power level is less than the specific power level, the DPD mode controller 110 controls the DPD unit 120 to operate in a bypass mode, that is, provides control so that the DPD unit 120 is powered off to minimize power consumed by the operation of the DPD unit 120. Otherwise, if the power level is not less than the specific power level, the DPD mode controller 110 determines whether the location of the assigned Tx symbol corresponds to an Up Link (UL) full duration.

If the location of the assigned Tx symbol corresponds to the UL full duration, the DPD mode controller 110 controls the DPD unit 120 to operate in a normal mode (or an active mode), that is, provides control so that the DPD unit 120 is powered on in a full Tx duration. Otherwise, if the location of the assigned Tx symbol does not correspond to the UL full duration, the DPD unit 120 is controlled to operate in a power saving mode (or a sleep mode) to reduce power consumption of an MS, that is, the DPD unit 120 is controlled to be powered on only in a specific Tx duration.

According to mode control of the DPD mode controller 110, the DPD unit 120 may output data, which is input from the modem 100, to the DAC 130 directly or by performing a DPD operation. If the DPD operation is performed, the amplitude/phase regulator 111 of the DPD unit 120 evaluates an amplitude and phase of the data input from the modem 100, and searches for an LUT having a satisfactory power level and frequency by using the first LUT 115. Thereafter, the amplitude/phase regulator 111 extracts a compensation value corresponding to the amplitude and phase of the input data from the found LUT, compensates for the amplitude and phase of the input data by using the extracted compensation value, and outputs the compensated data to the temperature compensator 113. The first LUT 115 stores one or more LUTs with respect to frequency. Each LUT stores a compensation value of an amplitude and phase of data for each power level at a specific frequency.

When data is input, the temperature compensator 113 measures a present temperature of the PA 150 by using the temperature sensor 117, and extracts a nonlinearity compensation value corresponding to the measured temperature from the second LUT 119. Thereafter, the temperature compensator 113 compensates for nonlinearity depending on the temperature by using the extracted nonlinearity compensation value, and outputs the compensated data to the DAC 130. The temperature sensor 117 is disposed near the PA 150 to measure the temperature of the PA 150. The second LUT 119 stores nonlinearity compensation values with respect to temperature.

The DAC 130 converts an input digital signal into an analog signal and then outputs the analog signal to the modulator/up-converter 140. The modulator/up-converter 140 converts an input baseband signal into a Radio Frequency (RF) signal and then outputs the RF signal to the PA 150. The PA 150 amplifies power of a Tx signal and then transmits the Tx signal through a Tx antenna.

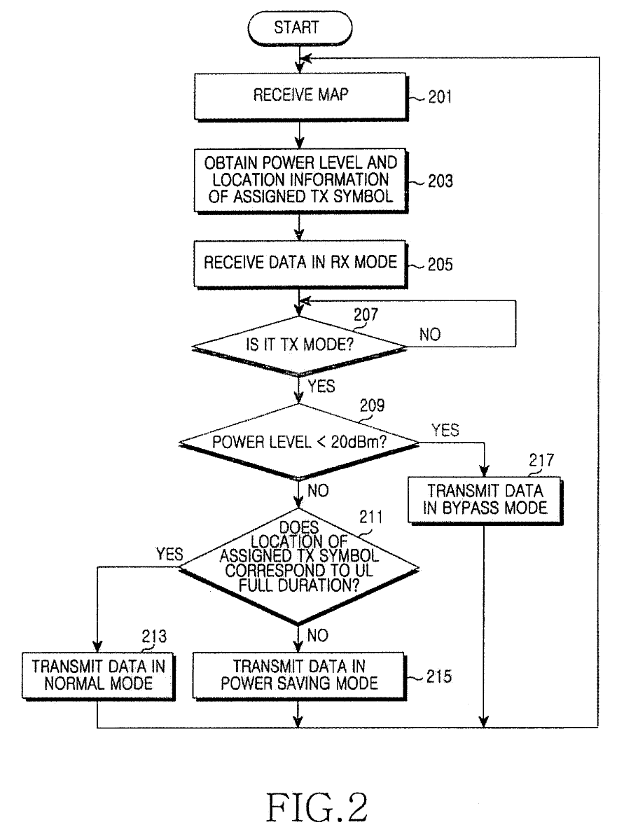

FIG. 2 illustrates a method of controlling a DPD mode in a portable communication terminal according to the present invention. The portable communication terminal described hereinafter employs a TDD scheme as an example. In a Tx mode, a transmitting part including a DPD unit is powered on while a receiving part is powered off. In an Rx mode, the receiving part is powered on while the transmitting part including the DPD unit is powered off.

Referring to FIG. 2, in step 201, an MS receives a MAP from a BS in the downlink. In step 203, the MS obtains a power level, which is to be output through a PA when data is transmitted, and location information of an assigned Tx symbol by using the received MAP. In step 205, the MS receives the data from the BS in the downlink in the Rx mode.

In step 207, the MS determines whether a present mode is the Tx mode, that is, whether a present link state is an uplink for transmitting data to the BS. If it is the Tx mode, in step 209, the MS determines whether the power level (i.e., antenna Tx power) is less than a specific power level, e.g., 20 dBm. If the power level is less than the specific power level, the PA of the MS maintains linearity and thus determines that there is no need to compensate for nonlinearity. Then, proceeding to step 217, the MS controls a DPD unit to operate in a bypass mode, that is, provides control so that the DPD unit is powered off to minimize power consumed by the operation of the DPD unit. Then, the MS transmits non-DPD data, and returning to step 201, repeats the subsequent steps.

Otherwise, if the power level is greater than 20 dBm, the PA of the MS cannot maintain linearity. Thus, the MS determines that there is a need to compensate for nonlinearity. Then, proceeding to step 211, the MS determines whether a location of the assigned Tx symbol corresponds to a UL full duration. If the location of the assigned Tx symbol corresponds to the UL full duration, in step 213, the MS controls the DPD unit to operate in a normal mode (or an active mode), that is, powers on the DPD unit in the full Tx duration. Then, the MS transmits DPD data, and returning to step 201, repeats the subsequent steps.

Otherwise, if the location of the assigned Tx symbol does not correspond to the UL full duration, in step 215, the MS controls the DPD unit to operate in a power saving mode (or a sleep mode) in order to reduce power consumption, that is, powers on the DPD unit only in a specific Tx duration. Then, the MS transmits DPD data, and returning to step 201, repeats the subsequent steps. In most cases, the MS is allocated with only a portion of the UL duration, and power consumption can be reduced by powering on the DPD unit only in the specific Tx duration.

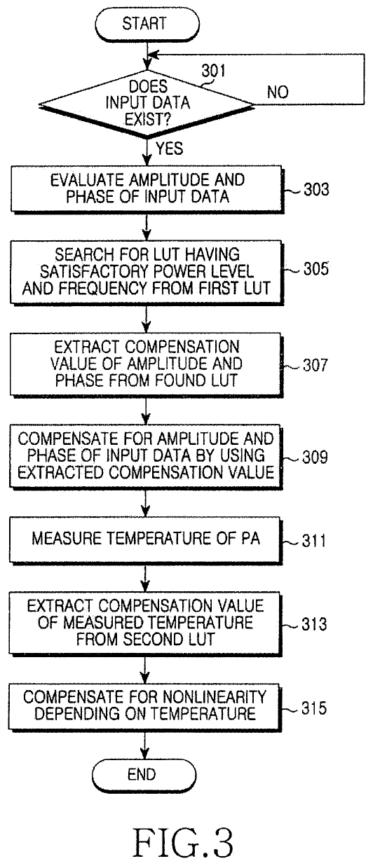

FIG. 3 illustrates a DPD method in a portable communication terminal according to the present invention.

Referring to FIG. 3, in step 301, a DPD unit determines whether there is data input from a modem. If the data input from the modem exists, in step 303, the DPD unit evaluates an amplitude and phase of the input data.

In step 305, the DPD unit searches for an LUT having a satisfactory power level and frequency from a first LUT. The power level can be evaluated using MAP information received from a BS. The frequency is information obtained when an initial negotiation process with the BS or a Relay Station (RS) is obtained. The first LUT stores one or more LUTs with respect to frequency. Each LUT stores a compensation value of an amplitude and phase of data for each power level at a specific frequency. That is, each LUT stores a compensation value of an amplitude and phase to be compensated for at a power level equal to or greater than the specific power level, e.g., 20 dBm.

In step 307, the DPD unit extracts a compensation value corresponding to the amplitude and phase of the input data from the found LUT. In step 309, the DPD unit compensates for the amplitude and phase of the input data by using the extracted compensation value, that is, performs a DPD operation on the input data.

In step 311, the DPD unit measures temperature of a PA. In step 313, the DPD unit extracts a nonlinearity compensation value corresponding to the measured temperature from a second LUT. Herein, the second LUT stores nonlinearity compensation values with respect to temperature, and the temperature of the PA can be measured using a temperature sensor disposed near the PA. In step 315, the DPD unit compensates for nonlinearity depending on the temperature by using the extracted nonlinearity compensation value.

Thereafter, the procedure of FIG. 3 ends.

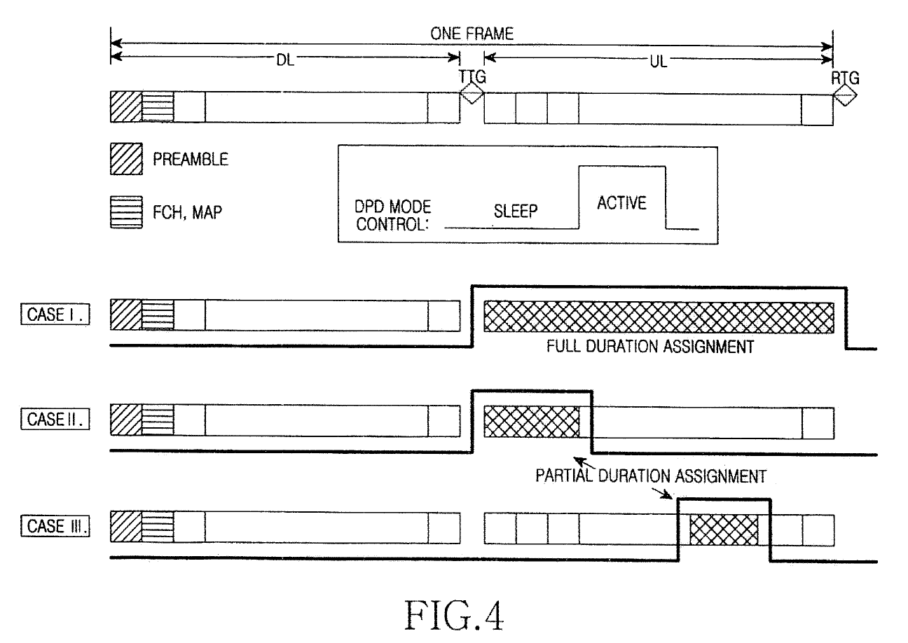

FIG. 4 illustrates preferred frame structure of a TDD system.

Referring to FIG. 4, one frame includes a UL duration and a DL duration. A MAP exists in a front portion of the DL duration. The MAP can be evaluated to determine a power level to be used in the UL duration and location information of Tx symbols on which data is carried. According to the present invention, the information is utilized to minimize an operation time of a DPD unit. Thus, power consumed in the DPD unit can be minimized, thereby maximizing overall system efficiency. In FIG. 4, three cases for controlling the aforementioned DPD modes are shown.

Case I is an example of a situation in which locations of Tx symbols on which the data is carried correspond to a UL full duration.

It is difficult for Case I to occur in a practical communication system because one BS covers a plurality of MSs, and time sharing exists between the MSs. Case II is an example of a situation in which only a front portion of the UL duration is allocated for transmitting only Channel Quality Indicator (CQI) signaling or the like indicating a state of the MS rather than transmitting data. Case III is an example of a situation in which only some symbols located in a middle portion are allocated so that data can be transmitted by carrying the data on specific symbols. Cases II and III occur more frequently than Case I. Under such situations, the DPD unit can be adaptively controlled to maximize efficiency.

The present invention can apply to an OFDM system. Although preferred embodiments of the present invention have been described above based on a Wimax system as an example of the OFDM system, the present invention can also apply to other OFDM systems such as a Long Term Evolution (LTE). That is, similar to the case of using the Wimax system in which MAP information is used to obtain a power level and location information of a Tx symbol assigned to a UL duration and in which the obtained information is used to determine a power on/off state of a DPD unit, the preferred embodiments of the present invention can apply to the LTE in which UL information provided after 4*TTI is obtained through a Physical Downlink Control CHannel (PDCCH) that occupies first three symbols of a Transmission Time Interval (TTI) of a DL signal.

Since an apparatus and method for compensating for nonlinearity of a portable communication terminal are provided herein, high costs and poor power efficiency resulting from additional conventionally used closed loop components such as a coupler, a mixer, and an ADC, are eliminated. In addition, power consumption can be minimized by allowing a DPD unit to operate in a specific high power duration having a nonlinear characteristic.

While the present invention has been shown and described with reference to certain preferred embodiments thereof, it will be understood by those skilled in the art that various changes in form and details may be made therein without departing from the spirit and scope of the present invention as defined by the appended claims and their equivalents. Therefore, the scope of the invention is defined not by the detailed description of the invention but by the appended claims and their equivalents, and all differences within the scope will be construed as being included in the present invention.

What is claimed is:

1. An apparatus for compensating for nonlinearity in a portable communication terminal, the apparatus comprising:
a modem for modulating Transmission (Tx) data input in a Tx mode so as to output modulated data;
a Digital Pre-Distortion (DPD) mode controller for obtaining power level information by using control information received from a Base Station (BS) and for determining a power on and off state of a DPD unit by using the obtained information in the Tx mode; and
the DPD unit, which is powered on and off under the control of the DPD mode controller, for outputting the modulated data input from the modem without performing a DPD operation when power is off, and for outputting the modulated data input from the modem by performing the DPD operation when power is on.

2. The apparatus of claim 1, wherein the DPD mode controller determines whether the power level is less than a reference power level, and if the power level is less than the reference power level, determines to power off the DPD unit, and if the power level is greater than the reference power level, determines to power on the DPD unit.

3. The apparatus of claim 2, wherein the reference power level is a power level at which a Power Amp (PA) has nonlinearity.

4. The apparatus of claim 2, wherein the DPD mode controller obtains location information of a Tx symbol assigned for uplink by using control information received from the BS, and, by using the obtained location information of the Tx symbol, if the location of the Tx symbol assigned for uplink corresponds to an uplink full duration, determines to power on the DPD unit in the uplink full duration, and if the location of the Tx symbol does not correspond to the uplink full duration, determines to power on the DPD unit only in a specific duration.

5. The apparatus of claim 1, wherein the DPD unit comprises:
an amplitude and phase regulator for evaluating an amplitude and phase of data input from the modem, searching for a Look-Up-Table (LUT) having a satisfactory power level and frequency obtained in an initial negotiation process by using a first LUT, extracting a compensation value corresponding to the amplitude and phase of the input data from the found LUT, compensating for the amplitude and phase of the input data by using the extracted compensation value, and outputting the compensated data; and
the first LUT for storing one or more LUTs with respect to frequency, wherein each LUT stores a compensation value of an amplitude and phase of data for each power level at a specific frequency.

6. The apparatus of claim 5, wherein the DPD unit comprises:
a temperature compensator for measuring temperature of a PA, when data is input from the amplitude and phase regulator, by using a temperature sensor, extracting a nonlinearity compensation value corresponding to the measured temperature from a second LUT, compensating for nonlinearity depending on the temperature by using the extracted nonlinearity compensation value, and outputting the compensated data; and
the second LUT for storing nonlinearity compensation values with respect to temperature.

7. A method of compensating for nonlinearity in a portable communication terminal, the method comprising:
obtaining power level information by using control information received from a BS;
determining a power on and off state of a Digital Pre-Distortion (DPD) unit by using the obtained information in a Transmission (Tx) mode; and
when power is off, non-performing a DPD operation on the modulated data input from a modem, and when power is on, performing the DPD operation on the modulated data.

8. The method of claim 7, wherein the determining of the power on/off state of the DPD unit comprises:
determining whether the power level is less than a reference power level;
if the power level is less than the reference power level, determining to power off the DPD unit; and
if the power level is greater than the reference power level, determining to power on the DPD unit.

9. The method of claim 8, wherein the reference power level is a power level at which a PA has nonlinearity.

10. The method of claim 8, wherein the determining to power on the DPD unit comprises:
obtaining location information of a Tx symbol assigned for uplink by using control information received from the BS;
determining, by using the obtained location information of the Tx symbol, whether a location of the Tx symbol assigned for uplink corresponds to an uplink full duration;
determining to power on the DPD unit in the uplink full duration, if the location of the Tx symbol assigned for uplink corresponds to the uplink full duration; and
determining to power on the DPD unit only in a specific duration, if the location of the Tx symbol does not correspond to the uplink full duration.

11. The method of claim 7, wherein the performing of the DPD operation comprises:
evaluating an amplitude and phase of data input from the modem;
searching for a Look-Up-Table (LUT) having a satisfactory power level and frequency obtained in an initial negotiation process by using a first LUT;
extracting a compensation value corresponding to the amplitude and phase of the input data from the found LUT; and
compensating for the amplitude and phase of the input data by using the extracted compensation value.

12. The method of claim 11, wherein the first LUT stores one or more LUTs with respect to frequency, and each LUT stores a compensation value of a data amplitude and phase for each power level at a specific frequency.

13. The method of claim 11, further comprising:
measuring temperature of a Power Amplifier (PA) by using a temperature sensor;
extracting a nonlinearity compensation value corresponding to the measured temperature from a second LUT; and
compensating for nonlinearity depending on the temperature by using the extracted nonlinearity compensation value.

14. The method of claim 13, wherein the second LUT stores nonlinearity compensation values with respect to temperature.
